(19) United States
(12) Patent Application Publication
(10) Pub. No.: US 2003/0107105 A1
(43) Pub. Date: Jun. 12, 2003

(54) Programmable chip-to-substrate interconnect structure and device and method of forming same

(76) Inventor: Michael N. Kozicki, Phoenix, AZ (US)

Correspondence Address: SNELL & WILMER, ONE ARIZONA CENTER, 400 EAST VAN BUREN, PHOENIX, AZ, 850040001

(21) Appl. No.: 10/255,222

(22) Filed: Sep. 26, 2002

Related U.S. Application Data
(63) Continuation-in-part of application No. 09/386,800, filed on Aug. 31, 1999, now Pat. No. 6,469,364.
(63) Continuation-in-part of application No. 10/118,276, filed on Apr. 8, 2002.
(60) Provisional application No. 60/325,354, filed on Sep. 26, 2001.

(51) Int. Cl. H01L 29/00

(52) U.S. Cl. 257/529

(57) ABSTRACT

A structure and system for forming an electrical interconnection between a microelectronic device and a substrate and a method of forming the interconnection are disclosed. The interconnection includes a first electrode formed on the microelectronic device, a second electrode formed on the substrate, and an ion conductor placed between the first and second electrodes. An electrical connection between the microelectronic device and the substrate is formed by applying a bias across the first and second electrodes to form a conductive region within the ion conductor.

### CROSS-REFERENCE TO RELATED APPLICATIONS

This application claims priority to and the benefit of U.S. Provisional Patent Application Serial No. 60/325,354, entitled CHIP-TO-PACKAGE CONNECTION SCHEME BASED ON PROGRAMMABLE METALLIZATION CELL TECHNOLOGY and filed on Sep. 26, 2001; and is a continuation-in-part of application Ser. No. 09/386,800, entitled PROGRAMMABLE INTERCONNECTION SYSTEM FOR ELECTRICAL CIRCUITS and filed Aug. 31, 1999; and is a continuation-in-part of application Ser. No. 10/118,276, entitled MICROELECTRONIC DEVICE, STRUCTURE, AND SYSTEM, INCLUDING A MEMORY STRUCTURE HAVING A VARIABLE PROGRAMMABLE PROPERTY AND METHOD OF FORMING THE SAME and filed Apr. 8, 2002, the contents of which are hereby incorporated by reference.

### 1. TECHNICAL FIELD

The present invention generally relates to microelectronic device packaging. More particularly, the invention relates to techniques and structures for forming an electrical interconnection between a microelectronic device and a substrate.

### 2. BACKGROUND INFORMATION

Microelectronic devices such as semiconductor devices are often packaged to protect the device from mechanical damage, chemical attack, light, extreme temperature cycles, and other environmental effects. In addition, the devices are often packaged to facilitate attachment of the device to a substrate such as a printed circuit board. In particular, the device package may facilitate attachment of the device to a substrate by providing mechanical support during the attachment process and by providing electrical connections between the device and the substrate.

Typical microelectronic device packages include wire bonds, a leadframe, or conductive bumps to form electrical connection between the microelectronic device and a portion of the package. As the density of electrical connections between the microelectronic device and the package increases, these traditional packaging schemes become increasingly problematic. Accordingly, improved methods and structures for forming electrical connections between an microelectronic device and another substrate or package and systems including the improved interconnections are desired.

### SUMMARY OF TIE INVENTION

The present invention provides improved apparatus and techniques for electrically and mechanically bonding a semiconductor device to another substrate such as an electronic package. While the way in which the present invention addresses the disadvantages of the prior art will be discussed in greater detail below, in general, the present invention provides a relatively inexpensive technique for electrically and mechanically bonding a device to a substrate that allows for a high density of interconnections between the device and substrate per surface area of the device.

In accordance with one embodiment of the invention, an interconnect structure includes an ion conductor and at least two electrodes spaced apart from each other. The interconnect structure is configured such that when a sufficient bias is applied across two of the electrodes, metal ions within the ion conductor migrate and alter a conductivity of at least a portion of the ion conductor. In accordance with one aspect of this embodiment, a first electrode is formed on a microelectronic device and a second electrode and an ion conductor are formed on a separate substrate. In this case, an electrical connection is formed by placing the device and the substrate in contact with each other such that the electrode on the device contacts the ion conductor on the substrate and then applying a bias across the first and second electrodes to form a relatively conductive region within the ion conductor. In accordance with additional aspects of this embodiment, either the microelectronic device, the substrate, or both may include sacrificial or temporary conductive paths to facilitate application of a bias across the first and second electrodes during the interconnect formation step.

In accordance with another embodiment of the invention, an interconnection may be dissolved or erased by applying a bias across a first and second electrode, wherein the applied bias is of an opposite polarity to the bias applied to form the interconnection.

In accordance with additional embodiments of the invention, the interconnections formed in accordance with the present invention are self-aligning, allowing for some misalignment of the first electrode on the device and the second electrode on the substrate, during the interconnect formation process.

In accordance with yet further embodiments of the invention, the interconnections are self repairing. In this case, if an interconnection becomes damaged for some reason and thus the resistance of the interconnect increases, the interconnect repairs itself, to lower the resistance through the interconnect, until the voltage drop is less than or equal to the threshold voltage for interconnect formation.

In accordance with various aspects of the exemplary embodiments of the invention, the interconnect structures also include conducting and/or insulating barrier layers.

In accordance with other embodiments of the invention, interconnect systems include programmable or selectable interconnect structures. In this case, the system includes an array of interconnect structures and a bias is applied across one or more of the structures to form the desired interconnects.

### BRIEF DESCRIPTION OF THE DRAWINGS

A more complete understanding of the present invention may be derived by referring to the detailed description, considered in connection with the figures, wherein like reference numbers refer to similar elements throughout the figures, and:

FIG. 1 illustrates an interconnect structure connecting a microelectronic device and a substrate;

FIGS. 2-4 illustrate a process for forming an interconnect structure in accordance with the present invention; and

FIG. 5 illustrates a plan view of a microelectronic device including portions of interconnect structures of the present invention.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION OF EXEMPLARY EMBODIMENTS

The present invention provides structures and techniques for forming electrical and mechanical connections between two substrates. While the invention may be practiced in connection with a providing electrical interconnections between a variety of devices and/or substrates, the invention is conveniently described below in connection with providing an electrical connection between a microelectronic device and a substrate such as a portion of a microelectronic device package.

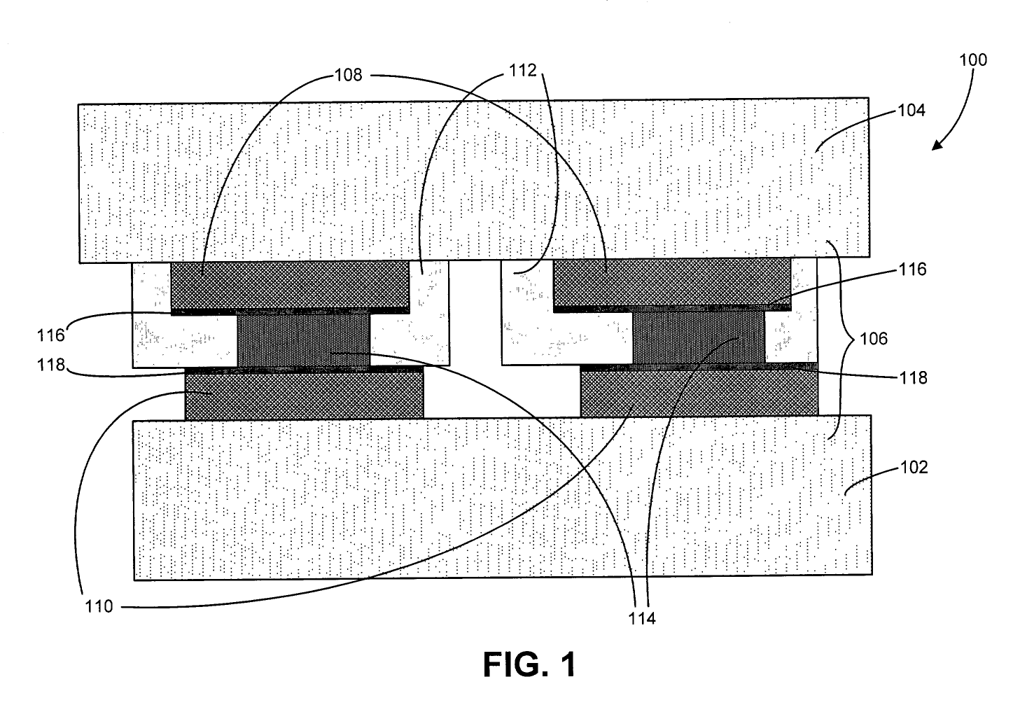

FIG. 1 illustrates an interconnect system 100 in accordance with the present invention. System 100 includes a microelectronic device 102, a substrate 104, and an interconnect 106, including a first electrode 108, a second electrode 110, and an ion conductor 112, coupling substrate 104 to device 102.

Generally, structure 100 is configured such that when a bias greater than a threshold voltage (V_{T}), discussed in more detail below, is applied across electrodes 108 and 110, the resistance across interconnect 106 changes. For example, in accordance with one embodiment of the invention, as a voltage V≧V_{T} is applied across electrodes 108 and 110, conductive ions within ion conductor 112 begin to migrate and form a region 114, which has an increased amount of conductive material compared to the remaining portion of ion conductor 112, at or near the more negative of electrodes 108 and 110. In some cases, region 114 may form an electrodeposit of conductive material. As region 114 forms, the resistance between electrodes 108 and 110 decreases. In the absence of any insulating barriers, which are discussed in more detail below, the threshold voltage required to grow region 114 from one electrode toward the other and thereby significantly reduce the resistance of the device is approximately the reduction/oxidation or “redox” potential of the system, typically a few hundred millivolts. If the same voltage is applied in reverse, region 114 will dissolve back into the ion conductor and interconnect 106 will return to a high resistance state.

In accordance with various embodiments of the invention, the volatility of interconnect 106 can be manipulated by altering an amount of energy (e.g., altering time, current, voltage, thermal energy, and/or the like) applied during a region 114 growth step. In particular, the greater the amount of energy (having a voltage greater than the threshold voltage for region 114 formation) applied during the growth process, the greater the growth of region 114 and hence the less volatile the interconnect.

Microelectronic device 102 may include any suitable device such as a microprocessor, a microcontroller, a memory circuit, or the like. In accordance with one exemplary embodiment of the invention, device 102 includes one or more electrodes 108, which form part of interconnect 106.

Substrate 104 may include a variety of materials such as ceramics, metal frames, plastic materials, and the like, which are typically used to facilitate coupling of a microelectronic device to another electronic device. Substrate 104 may also or alternatively include semiconductor material, e.g., another microelectronic device.

Electrodes 108 and 110 may be formed of any suitable conductive material. For example, electrodes 108 and 110 may be formed of doped polysilicon material or metal. In accordance with one exemplary embodiment of the invention, one of electrodes 108 and 110 is formed of a material including a metal that dissolves in ion conductor 114 when a sufficient bias (V≧V_{T}) is applied across the electrodes (an oxidizable electrode) and the other electrode is relatively inert and does not dissolve during operation of the programmable device (an indifferent electrode). For example, electrode 108 may be an anode during region 114 formation and be comprised of a material including silver or copper that dissolves in ion conductor 112 and electrode 110 may be a cathode during region 114 formation and be comprised of an inert material such as tungsten, nickel, molybdenum, platinum, metal suicides, and the like. Having at least one electrode formed of a material including a metal which dissolves in ion conductor 112 facilitates maintaining a desired dissolved metal concentration within ion conductor 112, which in turn facilitates rapid and stable region 114 formation within ion conductor 112.

Dissolution of region 114, if desired, preferably begins at or near the oxidizable electrode/ion conductor interface. Initial dissolution of region 114 at the oxidizable electrode/ion conductor interface may be facilitated by forming structure 106 such that the resistance at the oxidizable electrode/ion conductor interface is greater than the resistance at any other point along region 114, particularly, the interface between region 114 and the indifferent electrode.

One way to achieve relatively low resistance at the indifferent electrode is to form the electrode of relatively inert, non-oxidizing material such as platinum. Use of such material reduces formation of oxides at the interface between ion conductor 112 and the indifferent electrode as well as the formation of compounds or mixtures of the electrode material and ion conductor 112 material, which typically have a higher resistance than ion conductor 112 or the electrode material.

Relatively low resistance at the indifferent electrode may also be obtained by forming a barrier layer between the oxidizable electrode (anode during region 114 formation) and the ion conductor, wherein the barrier layer is formed of material having a relatively high resistance. Exemplary high resistance materials include layers (e.g., layer 116) of ion conducting material (e.g., AgₓO, AgₓS, AgₓSe, AgₓTe, where x≧2, Ag_{y}I, where y≧1, CuI₂, CuO, CuS, CuSe, CuTe, GeO₂, GeₓS_{1-z}, Ge_{z}Se_{1-z}, Ge_{z}Te_{1-z}, where z is greater than or equal to about 0.33, SiO₂, and combinations of these materials) interposed between ion conductor 112 and a metal layer such as silver. Such material layers may also be used as barrier layer 118, as discussed in more detail below.

Reliable growth and dissolution of region 114 can also be facilitated by providing a roughened indifferent electrode surface (e.g., a root mean square roughness of greater than about 1 nm) at the electrode/ion conductor interface. The roughened surface may be formed by manipulating film deposition parameters and/or by etching a portion of one of the electrode of ion conductor surfaces. During region 114 formation, relatively high electrical fields form about the spikes or peaks of the roughened surface, and thus regions with increased concentrations of conductive material are likely to form about the spikes or peaks. As a result, more reliable and uniform changes in region growth for an applied voltage across electrodes 108 and 110 may be obtained by providing a roughened interface between the indifferent electrode and ion conductor 112.

Oxidizable electrode material may have a tendency to thermally dissolve or diffuse into ion conductor 112, particularly during fabrication and/or formation of region 114. To reduce undesired diffusion of oxidizable electrode material into ion conductor 112, the oxidizable electrode may include a metal intercalated in a transition metal sulfide or selenide material such as Aₓ(MB₂)₁₋ₓ, where A is Ag or Cu, B is S or Se, M is a transition metal such as Ta, V, and Ti, and x ranges from about 0.1 to about 0.7. The intercalated material mitigates undesired thermal diffusion of the metal (Ag or Cu) into the ion conductor material, while allowing the metal to participate in region 114 growth upon application of a sufficient voltage across electrodes 108 and 110. For example, when silver is intercalated into a TaS₂ film, the TaS₂ film can include up to about 67 atomic percent silver. The Aₓ(MB₂)₁₋ₓ material is preferably amorphous to prevent undesired diffusion of the metal though the material. The amorphous material may be formed by, for example, physical vapor deposition of a target material comprising Aₓ(MB₂)₁₋ₓ.

α-AgI is another suitable material for the oxidizable electrode, as well as the indifferent electrode. Similar to the Aₓ(MB₂)₁₋ₓ material discussed above, α-AgI can serve as a source of Ag during region 114 formation-e.g., upon application of a sufficient bias, but the silver in the AgI material does not readily thermally diffuse into ion conductor 112. AgI has a relatively low activation energy for conduction of electricity and does not require doping to achieve relatively high conductivity. When the oxidizable electrode is formed of AgI, depletion of silver in the AgI layer may arise during formation of region 114, unless excess silver is provided to the electrode. One way to provide the excess silver is to form a silver layer adjacent the AgI layer as discussed above when AgI is used as a buffer layer. The AgI layer (e.g., layer 116 and/or 118) reduces thermal diffusion of Ag into ion conductor 112, but does not significantly affect conduction of Ag.

Other materials suitable for buffer layers 116 and/or 118 include GeO₂ and SiOₓ. Amorphous GeO₂ is relatively porous and will “soak up” silver during operation of device 106, but will retard the thermal diffusion of silver to ion conductor 112, compared to structures or devices that do not include a buffer layer. When ion conductor 112 includes germanium, GeO₂ may be formed by exposing ion conductor 112 to an oxidizing environment at a temperature of about 300° C. to about 800° C. or by exposing ion conductor 112 to an oxidizing environment in the presence of radiation having an energy greater than the band gap of the ion conductor material. The GeO₂ may also be deposited using physical vapor deposition (from a GeO₂ target) or chemical vapor deposition (from GeH₄ and an O₂).

In accordance with one embodiment of the invention, electrode 110 is formed of material suitable for use as an interconnect metal in semiconductor device manufacturing. For example, electrode 110 may form part of an interconnect structure within a semiconductor integrated circuit. In accordance with one aspect of this embodiment, electrode 110 is formed of a material that is substantially insoluble in material comprising ion conductor 112. Exemplary materials suitable for both interconnect and electrode 110 material include metals and compounds such as tungsten, nickel, molybdenum, platinum, metal silicides, and the like.

Similarly, electrode 108 may be formed of material suitable for use as bond pads on printed circuit boards. For example, electrode 108 may include copper or silver bond pad material as is commonly found on printed circuit boards.

Layers 116 and/or 118 may also include a material that restricts migration of ions between conductor 112 and the electrodes. In accordance with exemplary embodiments of the invention, a barrier layer includes conducting material such as titanium nitride, titanium tungsten, a combination thereof, or the like. The barrier may be electrically indifferent, i.e., it allows conduction of electrons through structure 106, but it does not itself contribute ions to conduction through structure 106. An electrically indifferent barrier may facilitate an “erase” or dissolution of region 114 when a bias is applied which is opposite to that used to grow region 114. In addition, use of a conducting barrier allows for the “indifferent” electrode to be formed of oxidizable material because the barrier prevents diffusion of the electrode material to the ion conductor.

Ion conductor 112 is formed of material that conducts ions upon application of a sufficient voltage. Suitable materials for ion conductor 112 include glasses and semiconductor materials. In one exemplary embodiment of the invention, ion conductor 112 is formed of chalcogenide material.

Ion conductor 112 may also suitably include dissolved conductive material. For example, ion conductor 112 may comprise a solid solution that includes dissolved metals and/or metal ions. In accordance with one exemplary embodiment of the invention, conductor 112 includes metal and/or metal ions dissolved in chalcogenide glass. An exemplary chalcogenide glass with dissolved metal in accordance with the present invention includes a solid solution of AsₓS₁₋ₓ—Ag, GeₓSe₁₋ₓ—Ag, GeₓS₁₋ₓ—Ag, AsₓS₁₋ₓ—Cu, GeₓSe₁₋ₓ—Cu, GeₓS₁₋ₓ—Cu, GeₓTe₁₋ₓ—Ag, AsₓTe₁₋ₓ—Ag where x ranges from about 0.1 to about 0.5, other chalcogenide materials including silver, copper, combinations of these materials, and the like. In addition, conductor 112 may include network modifiers that affect mobility of ions through conductor 112. For example, materials such as metals (e.g., silver), halogens, halides, or hydrogen may be added to conductor 112 to enhance ion mobility of conductor 112.

A solid solution suitable for use as ion conductor 112 may be formed in a variety of ways. For example, the solid solution may be formed by depositing a layer of conductive material such as metal over an ion conductive material such as chalcogenide glass and exposing the metal and glass to thermal and/or photo dissolution processing. In accordance with one exemplary embodiment of the invention, a solid solution of As₂S₃—Ag is formed by depositing As₂S₃ onto a substrate, depositing a thin film of Ag onto the As₂S_{3,}, and exposing the films to light having energy greater than the optical gap of the As₂S_{3,}—e.g., light having a wavelength of less than about 500 nanometers. If desired, network modifiers may be added to conductor 112 during deposition of conductor 112 (e.g., the modifier is in the deposited material or present during conductor 112 material deposition) or after conductor 112 material is deposited (e.g., by exposing conductor 112 to an atmosphere including the network modifier).

In accordance with another embodiment of the invention, a solid solution may be formed by depositing one of the constituents onto a substrate or another material layer and reacting the first constituent with a second constituent. For example, germanium (preferably amorphous) may be deposited onto a portion of a substrate and the germanium may be reacted with H₂Se to form a Ge—Se glass. Similarly, As can be deposited and reacted with the H₂Se gas, or arsenic or germanium can be deposited and reacted with H₂S gas. Silver or other metal can then be added to the glass as described above.

In accordance with one aspect of this embodiment, a solid solution ion conductor 112 is formed by depositing sufficient metal onto an ion conductor material such that a portion of the metal can be dissolved within the ion conductor material and a portion of the metal remains on a surface of the ion conductor to form an electrode (e.g., electrode 108).

An amount of conductive material such as metal dissolved in an ion conducting material such as chalcogenide may depend on several factors such as an amount of metal available for dissolution and an amount of energy applied during the dissolution process. However, when a sufficient amount of metal and energy are available for dissolution in chalcogenide material using photodissolution, the dissolution process is thought to be self limiting, substantially halting when the metal cations have been reduced to their lowest oxidation state. In the case of As₂S₃—Ag, this occurs at Ag₄As₂S₃=2Ag₂S+As₂S, having a silver concentration of about 44 atomic percent. If, on the other hand, the metal is dissolved in the chalcogenide material using thermal dissolution, a higher atomic percentage of metal in the solid solution may be obtained, provided a sufficient amount of metal is available for dissolution.

In accordance with a further embodiment of the invention, the solid solution is formed by photodissolution to form a macrohomogeneous ternary compound and additional metal is added to the solution using thermal diffusion (e.g., in an inert environment at a temperature of about 85° C. to about 150° C.) to form a solid solution containing, for example, about 30 to about 50, and preferably about 34 atomic percent silver. Ion conductors having a metal concentration above the photodissolution solubility level facilitates formation of regions 114 that are thermally stable at temperatures up to about 150° C. Alternatively, the solid solution may be formed by thermally dissolving the metal into the ion conductor at the temperature noted above; however, solid solutions formed exclusively from photodissolution are thought to be less homogeneous than films having similar metal concentrations formed using photodissolution and thermal dissolution.

Ion conductor 112 may also include a filler material, which fills interstices or voids. Suitable filler materials include non-oxidizable and non-silver based materials such as a non-conducting, immiscible silicon oxide and/or silicon nitride, having a cross-sectional dimension of less than about 1 nm, which do not contribute to the growth of an region 114. In this case, the filler material is present in the ion conductor at a volume percent of up to about 5 percent to reduce a likelihood that region 114 will spontaneously dissolve into the supporting ternary material as the interconnect structure is exposed to elevated temperature. Ion conductor 112 may also include filler material to reduce an effective cross-sectional area of the ion conductor. In this case, the concentration of the filler material, which may be the same filler material described above but having a cross-sectional dimension up to about 50 nm, is present in the ion conductor material at a concentration of up to about 50 percent by volume. The filler material may also include metal such as silver or copper to fill the voids in the ion conductor material.

In accordance with one exemplary embodiment of the invention, ion conductor 112 includes a germanium-selenide glass with silver diffused in the glass. Germanium selenide materials are typically formed from selenium and Ge(Se)_{4/2} tetrahedra that may combine in a variety of ways. In a Se-rich region, Ge is 4-fold coordinated and Se is 2-fold coordinated, which means that a glass composition near Ge_{0.20}Se_{0.80} will have a mean coordination number of about 2.4. Glass with this coordination number is considered by constraint counting theory to be optimally constrained and hence very stable with respect to devitrification. The network in such a glass is known to self-organize and become stress-free, making it easy for any additive, e.g., silver, to finely disperse and form a mixed-glass solid solution. Accordingly, in accordance with one embodiment of the invention, ion conductor 112 includes a glass having a composition of Ge_{0 17}Se_{0·83} to Ge_{0.25}Se_{0.75}.

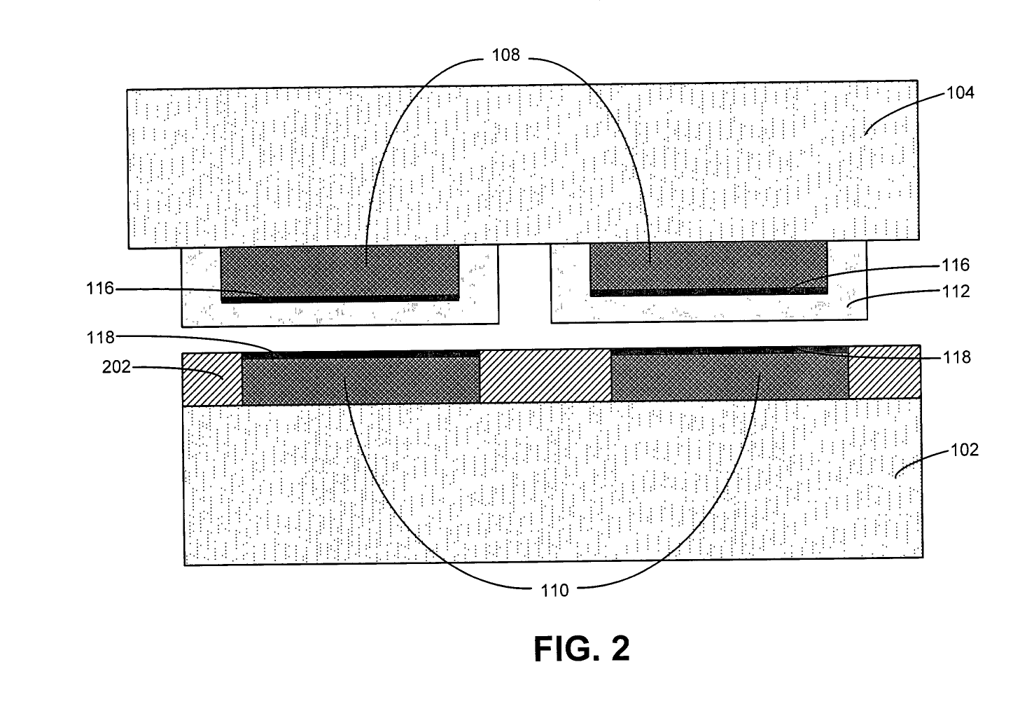

FIGS. 2-4 illustrate a method of forming an interconnect between device 102 and substrate 104 in accordance with the present invention. The method described below provides a technique for forming self-aligned interconnections, which allows for some misalignment or offset between electrode or contact regions on device 102 and substrate 104.

With reference to FIGS. 1 and 2, a first portion of interconnect 106 is formed on device 102 and a second portion is formed on substrate 104. In accordance with an exemplary embodiment of the invention, a first electrode 110 is formed on substrate 102 by, for example deposition and etch or damascene techniques.

To facilitate electrical contact to electrode 110 during region 114 formation, a sacrificial connector 202 may be formed on a surface of device 102. Sacrificial connector 202 may be formed of any suitable conducting material such as silver, be patterned using deposition and etch or damascene processing, and be removed during subsequent processing. The use of sacrificial layer 202 allows multiple electrodes 110 to be coupled together, so that multiple interconnects 106 may be formed simultaneously. Alternatively, peripheral bias pads may be formed on device 102 to allow voltages to be applied to certain pads within a selected area of device 102. Device 102 may also include insulating and/or passivation materials on the top surface to provide protection to portions of device 102.

Contact 108 and ion conductor 112 are formed on substrate 104 using similar techniques. For example, contact 108 may be formed by depositing electrode 108 material, patterning the material, and etching the material to form a desired pattern of electrodes 108. Then, ion conductor 112 material is deposited over the electrode using techniques described above. In accordance with one exemplary embodiment of the invention, substrate 104 is a microelectronic package including contact pads, typically formed of copper or silver (which form electrodes 108) and ion conductor 112 material is deposited onto the contact pads. If desired, the ion conductor material may be patterned and etched using photolithography techniques or by using high-resolution, multi-layer patterning techniques as described in U.S. Pat. No. 5,314,772, entitled High Resolution, Multi-Layer Resist for Microlithography and Method Therefore, issued to Kozicki et al. on May 24, 1994, the contents of which are hereby incorporated herein by reference. Alternatively, a solid layer of ion conductor may span between substrate 104 and device 102. In this case, excess ion conductor material that does not form region 114 may be removed using selective etching processes after region 114 is formed.

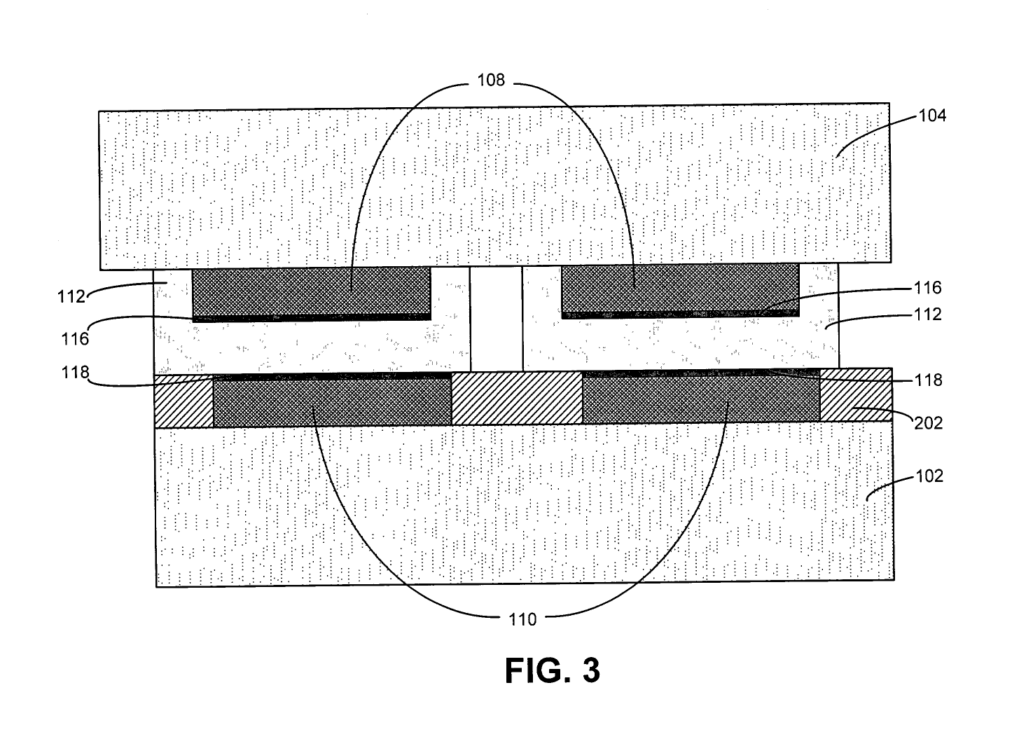

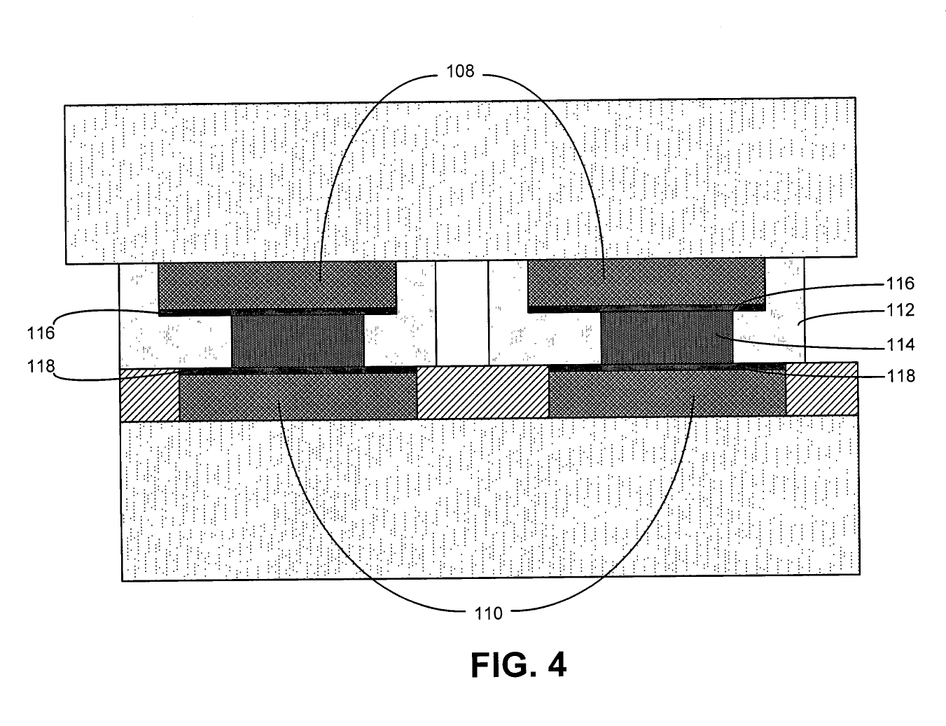

With reference to FIG. 3, once electrodes 108, 110 and ion conductor 112 are formed, device 102 and substrate 104 are placed in contact with each other such that electrodes 108 and 110 are in substantial alignment with each other. Device 102 and substrate 104 are then pressed together such that electrodes 110 are in contact with material 112. Next, a bias (V>V_{T}) is applied across electrode 108 and 110 to grow a conductive region 114 from the more positive electrode 108 toward the more negative electrode 110, as illustrated in FIG. 4. Once region 114 has formed, sacrificial layer 202 may be removed using any suitable wet or dry etching process or by photodecomposition.

In accordance with one embodiment of the invention, the temperature of structure 106 is increased during region 114 formation. In this case, the threshold voltage, V_{T}, deceases and less voltage is required to grow region 114. By way of particular example, region 114 is formed by heating structure 106 to a few hundred degrees Celsius (e.g., 200° C.) and applying a few hundred milliamps (e.g., 200 mA) across electrodes 108 and 110. In general, the voltage drop across electrodes 108 and 110 will not be greater than V_{T}, which is typically about 0.2V. Thus, if interconnect 106 experiences a higher current than expected, due to, for example, new or harsh operational requirements, region 114 will grow to maintain a voltage drop less than V_{T}. Further, any increased heating which occurs as a result of increased current passing through structure 116 reduces an amount of voltage required to grow region 114 and thus further facilitates growth of region 114.

Region 114 is generally self-repairing during operation of device 102. If the current passing through structure 106 causes a voltage drop greater than V_{T}, then region 114 will continue to grow until the voltage drop is less than V_{T}.

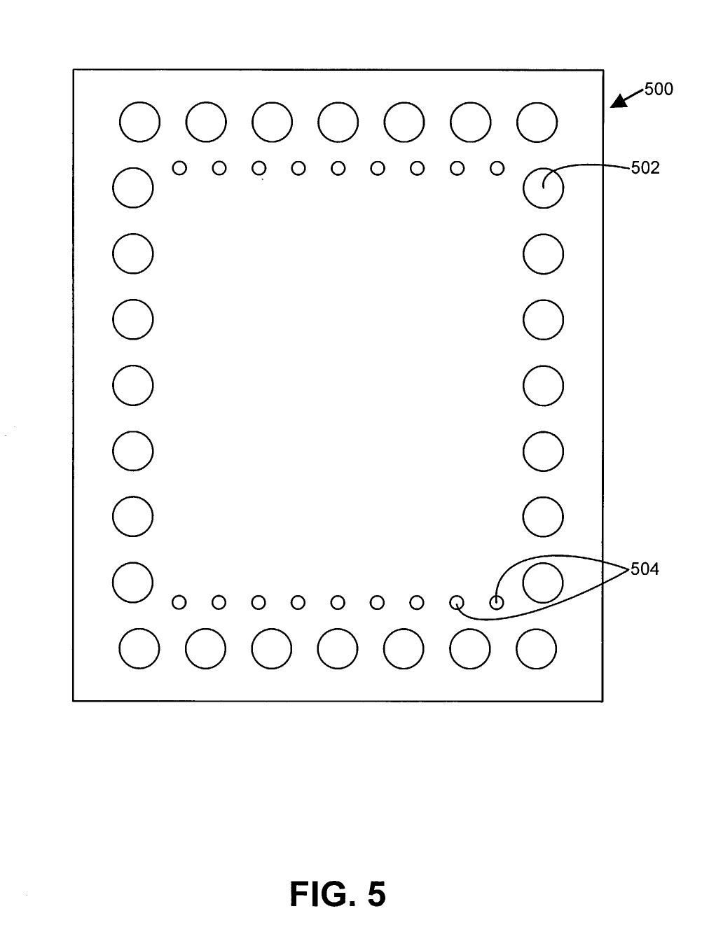

In accordance with an additional embodiment of the invention, interconnect structures, devices, and systems, may include both conventional interconnections and interconnections formed in accordance with the present invention. In this case, as illustrated in FIG. 5, a microelectronic device 500 may include conventional interconnections 502 such as wire bonds, leadframes, or conductive bumps and electrochemical interconnects 504.

In accordance with another embodiment of the invention, device 102 and/or substrate 104 include a standard array of electrodes and ion conductor portions and only a portion of the array of electrodes are exposed to a voltage bias to form interconnects 106. Use of a selectable array of electrodes facilitates flexible manufacturing of versatile interconnect systems because one array may be configured in a variety of ways, depending on a desired layout for the interconnections.

The present invention has been described above with reference to exemplary embodiments. Those skilled in the art having read this disclosure will recognize that changes and modifications may be made to the embodiments without departing from the scope of the present invention. For instance, the present invention has been described in connection with coupling a microelectronic device to a microelectronic device package; however, the interconnects described herein can be used to couple any electronic device to another structure These and other changes or modifications are intended to be included within the scope of the present invention, as expressed in the following claims.

We claim:

1. An interconnect for coupling a microelectronic device to a substrate, the interconnect comprising:
a first electrode;
a second electrode; and
an ion conductor interposed between the first electrode and the second electrode.

2. The interconnect of claim 1, wherein the first electrode is formed on the microelectronic device.

3. The interconnect of claim 1, wherein the second electrode is formed on the substrate.

4. The interconnect of claim 1, wherein the ion conductor is formed of a solid solution of a chalcogenide material and a metal.

5. The interconnect of claim 4, wherein the metal is selected from the group consisting of silver and copper.

6. The interconnect of claim 4, wherein the chalcogenide material is selected from the group consisting of AsₓS₁₋ₓ—Ag, GeₓSe₁₋ₓ—Ag, GeₓS₁₋ₓ—Ag, AsₓS₁₋ₓ—Cu, GeₓSe₁₋ₓ—Cu, GeₓS₁₋ₓ—Cu, GeₓTe₁₋ₓ—Ag, and AsₓTe₁₋ₓ—Ag.

7. The interconnect of claim 1, wherein the first electrode comprises a material selected from the group consisting of silver, copper, and α-AgI, Aₓ(MB₂)₁₋ₓ, where A is Ag or Cu, B is S or Se, M is a transition metal.

8. The interconnect of claim 1, wherein the second electrode comprises a material selected from the group consisting of tungsten, nickel, molybdenum, platinum, and metal suicides.

9. The interconnect of claim 1, further comprising a sacrificial connector layer coupled to the first electrode.

10. The interconnect of claim 1, further comprising a barrier layer proximate the ion conductor.

11. The interconnect of claim 10, wherein the barrier layer comprises an insulating material.

12. The interconnect of claim 10, wherein said barrier layer comprises a conductive material.

13. A method of forming an electrical connection between a microelectronic device and a substrate, the method comprising the steps of:
forming a first electrode on a surface of a microelectronic device;
forming a second electrode on a surface of a substrate;
forming an ion conductor overlying the second substrate;
placing the first electrode in contact with the ion conductor; and
applying a first bias across the first electrode and the second electrode to form a conductive region within the ion conductor.

14. The method of forming an electrical connection of claim 13, further comprising the step of exposing the ion conductor to an elevated temperature to facilitate growth of a conductive region within the ion conductor.

15. The method of forming an electrical connection of claim 13, further comprising the step of forming a sacrificial connector on a surface of the microelectronic device.

16. The method of forming an electrical connection of claim 13, further comprising the step of applying a second bias across the first electrode and the second electrode to dissolve the conductive region.

17. An interconnect system comprising:
a microelectronic device having a first electrode;
a substrate including a second electrode; and
an ion conductor interposed between the first electrode and the second electrode.

18. The interconnect system of claim 17, further comprising a conductive region formed within the ion conductor.

19. The interconnect system of claim 17, further comprising a barrier layer adjacent the ion conductor.

20. The interconnect system of claim 17, further comprising conductive bumps formed on the microelectronic device.
